(19) United States
(12) Patent Application Publication
(10) Pub. No.: US 2010/0323477 A1
(43) Pub. Date: Dec. 23, 2010

(54) INTERCONNECTIONS OF AN INTEGRATED ELECTRONIC CIRCUIT

(75) Inventors: Vincent Arnal, Grenoble (FR); Joaquin Torres, St. Martin le Vinoux (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS SA, Montrouge (FR)

(21) Appl. No.: 12/854,077

(22) Filed: Aug. 10, 2010

Related U.S. Application Data
(62) Division of application No. 12/013,279, filed on Jan. 11, 2008.

(30) Foreign Application Priority Data
Jan. 11, 2007 (FR) 07 00197

(51) Int. Cl. H01L 21/98; H01L 21/768; H01L 21/60

(52) U.S. Cl. 438/121; 438/637; 257/E21.506; 257/E21.575; 257/E21.705

(57) ABSTRACT

A method to fabricate an integrated electronic circuit includes superimposing insulating layers and metal elements distributed within said insulating layers. Each insulating layer comprises a first level within which the metal elements lie substantially in the plane of the first level, and a second level traversed by the metal elements in a direction substantially perpendicular to the plane of the second level, so as to come into contact with at least one metal element of the first level. The levels also comprise insulation zones for insulating the metal elements from each other. In one insulating layer, at least one of the levels comprises at least two insulation zones respectively realized of a first material and a second material which are different from each other.

### CROSS-REFERENCE TO RELATED APPLICATION

This application is a divisional of U.S. patent application Ser. No. 12/013,279 filed Jan. 11, 2008, now pending, which is incorporated herein by reference in its entirety.

### BACKGROUND

1. Technical Field

This invention relates to the domain of integrated electronic circuits.

2. Description of the Related Art

Integrated circuits are generally structured into an active part (the “front end”) in which are the devices such as transistors, and a superimposed passive part (the “back end”). The back end is dedicated to transferring signals from one transistor type of device to another.

The back end has a structure in multiple insulating layers, within which lie metal elements, typically metal interconnections, but also capacitors, coils, antennas, etc.

Lines are metal interconnections which, for each layer, lie within a first level of the layer in the plane of said level, and define a pattern. Vias are metal interconnections which, for each layer, traverse a second level in a direction perpendicular to the plane of said second level, and which connect lines from one layer to another.

Each layer thus comprises a first level, called the interconnection level, inside which lie the lines, and a second level called the contact level, inside which lie the vias.

Insulation zones, generally realized of a dielectric material, separate the metal interconnections from each other. The material of the insulation zones is chosen so as to limit parasitic capacitance between the metal interconnections.

The capacitance between interconnections increases with the permittivity between these interconnections, and decreases with the distance between them. The race towards miniaturization and performance optimization has therefore led to choosing a dielectric with a relatively weak permittivity “k”, typically less than 4.2, or even choosing to separate the interconnections by air gaps. ULK (“Ultra Low k”) dielectrics thus present a permittivity of less than 4.2. ELK (“Extreme Low k”) dielectrics present a permittivity coefficient of less than 2.5.

However, integrated circuits realized with ULK dielectrics or with air gaps are likely to be damaged relatively easily, particularly during fabrication. For example, a layer realized of a porous ULK dielectric can be broken off relatively easily during a CMP (Chemical Mechanical Polishing) step.

Mechanical failures also include a lack of resistance to the stresses created by welding connections and injecting resin around the circuit.

The document by Y. N. Su et al. entitled “Integration of Cu and Extra Low-k Dielectric (k=2.5˜2.2) for 65/45/32 nm Generations”, Electron Devices Meeting 2005, IEDM technical digest, IEEE International, 5-7 Dec. 2005, describes a hybrid structure, in which the dielectric material used for the interconnection levels has a lower permittivity than that of the dielectric material used for the contact levels. Such structures have a satisfactory mechanical resistance, but the capacitance between interconnections may be relatively high.

### BRIEF SUMMARY

One embodiment improves the performance of integrated electronic circuits.

One embodiment provides an integrated electronic circuit comprising superimposed insulating layers and metal elements distributed throughout said insulating layers. Each insulating layer comprises a first level, within which the metal elements lie substantially within the plane of said first level, and a second level, traversed by the metal elements in a direction substantially perpendicular to the plane of said second level, so as to come into contact with at least one metal element of the first level. The first level and the second level both comprise insulation zones which isolate the metal elements from each other. For at least one insulating layer, at least one of the levels of said at least one insulating layer comprises at least two insulation zones respectively realized of a first material and a second material which are not the same.

“Materials which are not the same” is understood to mean materials which differ in the chemical composition, structurally, or in some other way. For example, the two materials have the same chemical composition, but one of the materials is relatively dense and the other relatively porous, for example a material of a porosity exceeding 30% by volume. The first and second materials can typically have different mechanical properties, for example a Young's modulus or a Poisson ratio at least 10% higher or lower from one material to the other, different permittivities, and/or different thermal conductivity coefficients. At least one insulation zone can even integrate an air gap, meaning that one of the dielectric materials, for example the second, is air.

Alternatively, the two materials may be solids, for example two dielectric materials. The dielectric materials usable for insulation zones include silicon dioxide (SiO₂), materials based on fluorinated or carbon-doped silicon dioxide, whether dense or porous, carbon-doped polymer materials, etc.

In this manner there are at least two groups of insulation zones for the same level, each group associated with a given material. The use of at least two different materials within the same level offers more flexibility in finding a compromise between the diverse performances required for the circuit.

For example, the first material may present a permittivity of about 5%, preferably 10%, or even 15% or above, greater than that of the second material, and/or a Young's modulus of about 5%, preferably 10%, or even 15% or above, greater than that of the second material. This juxtaposition of insulation zones of different materials allows reconciling electrical performance with good mechanical resistance.

In addition, the juxtaposition of different zones within the same level may allow better heat removal, via zones presenting a higher thermal conductivity coefficient. In particular, the materials presenting a relatively low permittivity, for example porous materials, generally present a relatively low thermal conductivity coefficient, such that the juxtaposition of zones having different permittivity coefficients allows satisfactory heat removal.

There can be two distinct materials, or there can be more.

It is advantageous if said at least one level comprising at least two insulation zones realized of different materials is a second level. In other words, in the case where the metal elements comprise metal interconnections, it is within the contact level that the insulation zones realized of distinct materials are found. As the metal elements of the second level occupy less area than the metal elements of the first level, the space available for the different insulation zones is relatively high in the second level. Thus there is a certain flexibility in choosing the locations for the different insulation zones.

Alternatively, one may choose to place the different insulation zones within the first level, or within both levels.

It is advantageous if at least one insulation zone realized of the first material, in the second level, is located adjacent to a corresponding metal element of the first level. In this manner, one can adjust the various capacitance values induced by each first level metal element corresponding to such an insulation zone. Because of the relatively high surface area occupied by the first level elements, it is primarily the capacitances induced by the first level metal elements which are likely to reduce the circuit's performance.

Of course, such a distribution of the insulation zones in no way limits the scope of the invention.

It is advantageous if at least one second level insulation zone adjacent to the corresponding metal element is self-aligned with said metal element. This avoids an overlay between an insulation zone and the corresponding metal element, and a resulting imprecision in the parasitic capacitance values. This also avoids the need for a supplemental mask for the deposition of self-aligned insulation zones during the fabrication of the circuit.

Of course, the insulation zones do not have to be self-aligned.

It is advantageous if the first material presents a permittivity and a Young's modulus greater than those of the second material. Thus one may obtain relatively low capacitances between metal elements of the same first level, due to the relatively low values of the fringe capacitances, as explained below with reference to FIG. 2. As an example, the permittivity for the first material can be at least 1%, preferably at least 10%, or even at least 15% above that of the second material, and the Young's modulus of the first material can be at least 10%, preferably at least 15%, or even at least 20%, above that of the second material.

Alternatively, the first material can present a permittivity coefficient and/or a Young's modulus below those of the second material. For example, two first level metal elements belonging to successive insulating layers, and sandwiching the corresponding insulation zone, can thus be separated by a zone presenting a relatively low permittivity, such that the capacitance between these elements is also relatively low.

One embodiment provides an electronic board comprising an electronic chip comprising a package and an integrated electronic circuit according to the first aspect of the invention.

One embodiment provides a method for fabricating an integrated electronic circuit comprising superimposed insulating layers and metal elements distributed through said insulating layers, the method comprising, for at least one insulating layer of said superimposed layers:

a/ depositing a first dielectric material onto a substrate so as to form a layer,

b/ forming a trench in the layer,

c/ filling the trench with a second dielectric material different from the first dielectric material, such that the layer now comprises insulation zones of the first dielectric material and insulation zones of the second dielectric material, and

d/ executing a smoothing step so as to substantially eliminate the second dielectric material from the zones on the surface of the layer which correspond to the insulation zones of the first dielectric material,

e/ forming another trench in the layer, and

f/ filling in said trench with a metal, so as to form a metal element.

This process allows obtaining an electronic circuit according to one embodiment.

Steps b/, c/ and d/ can be performed before or after steps e/ and f/.

The process can comprise, particularly in the context of a dual damascene method, additional steps consisting of forming a third trench and filling in said third trench with metal so as to form another metal element. This last step, consisting of filling the third trench, and step f/ can be realized simultaneously. In addition, the third trench formation step can occur before or after step f/.

In general, the invention is not limited by the order in which the steps are executed.

The locations of two of the trenches can be combined and the same mask may be used for the steps in which said trenches are formed. These two trenches are thus self-aligned.

The process can additionally comprise a step of removing at least part of the first dielectric material, through contact with an agent that removes the first material. An electronic circuit comprising air gaps is thus obtained.

Alternatively, this removal step does not take place, such that the circuit retains zones of the first dielectric material and zones of the second dielectric material.

Other features and advantages of the invention will become apparent in the embodiments described below with respect to the figures.

### BRIEF DESCRIPTION OF THE SEVERAL VIEWS OF THE DRAWINGS

FIG. 1 shows an example of a portion of an electronic circuit with a known prior art hybrid structure.

FIGS. 2 and 3 respectively show two examples of a portion of an electronic circuit according to two embodiments of the invention.

FIGS. 4A to 4G show an example of a circuit fabrication process according to one embodiment of the invention.

FIGS. 5A to 5D show an example of a circuit fabrication process according to one embodiment of the invention.

FIG. 6 shows an example of an electronic board according to one embodiment of the invention.

### DETAILED DESCRIPTION

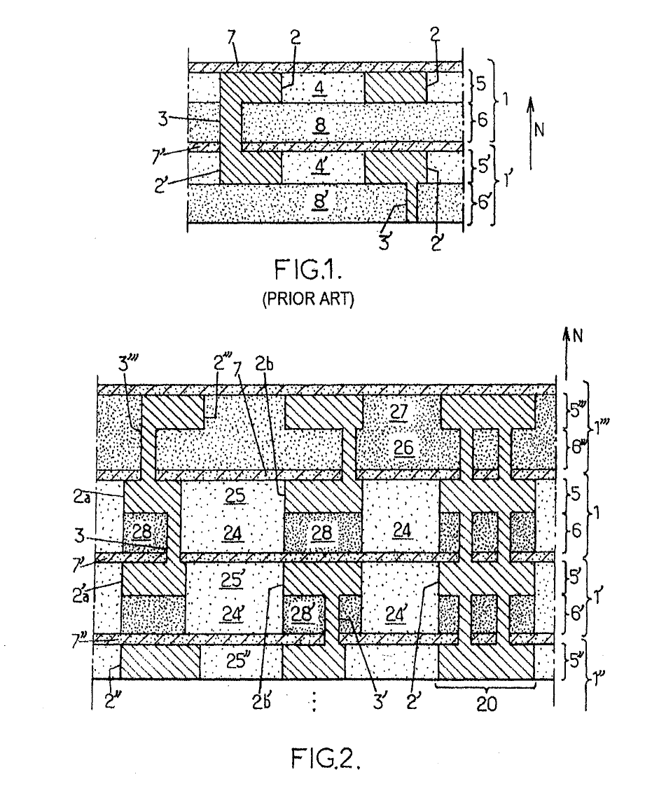

For clarity, the dimensions of the various elements represented in these figures are not proportional to their actual dimensions. FIGS. 1 to 5D are cross-section views of wafer segments which are substantially flat, viewed in a plane perpendicular to the surface of the wafer. The substrate is found in the lower part of each figure, and N indicates a direction perpendicular to the surface of the substrate, pointing towards the top of the figures. In what follows, the terms “on”, “under”, “upper”, “lower”, “above” and “below” are used with reference to this orientation. “On” is understood to mean “directly on” as well as “indirectly on”, meaning that a layer deposited “on” another may be completely separated from said other layer by at least one other layer.

In the figures, the same numbers are used to indicate similar or identical objects.

FIG. 1 shows a portion of a known prior art integrated electronic circuit. In addition to a front end not represented, the circuit comprises superimposed insulating layers, some of which are represented with the reference labels 1 and 1′. The number of insulating layers can, for example, be seven or eight.

The insulating layers 1, 1′ are separated from each other by a thin barrier of dielectric 7, 7′.

Each layer 1, 1′ comprises a level of interconnections 5, 5′ and a level of contacts 6, 6′, within which lie metal elements 2, 3, 2′. The metal elements comprise lines 2, 2′ lying within the interconnection levels 5, 5′ and in the plane of the corresponding interconnection level 5, 5′, and vias 3, 3′ which traverse the contact levels 6, 6′ in a direction substantially perpendicular to the plane of the contact level in order to connect two lines 2, 2′ in two separate insulating layers.

The lines and vias are isolated from each other by insulation zones 4, 4′, 8, 8′, generally of dielectric. In the case of a hybrid structure, the zones 4, 4′ of the interconnection levels 5, 5′ are realized of a material different from the one used for the zones 8, 8′ of the contact levels 6, 6′. The dielectric material used for the zones 4, 4′ presents a lower permittivity than that of the material used for the zones 8, 8′.

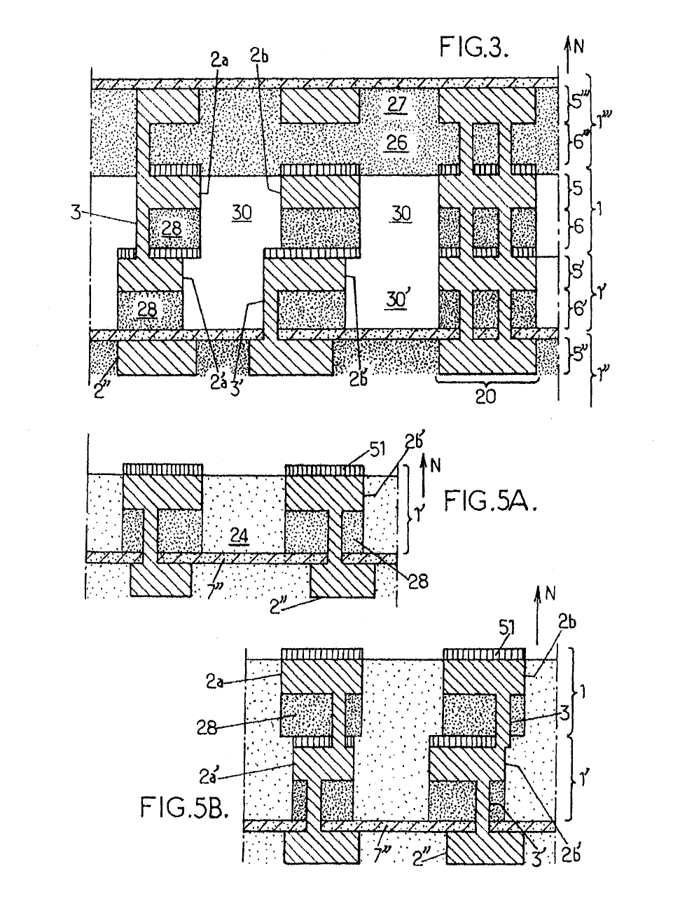

FIG. 2 shows an example of a portion of electronic circuit according to one embodiment of the invention. The back end of this circuit comprises superimposed insulating layers 1, 1′, 1″, 1′″, separated from each other by thin barriers of dielectric 7, 7′, 7″. The layers 1, 1′, 1″, 1′″ can, for example, have a thickness on the order of a hundred nanometers, for example from 50 nm to 1 μm. The barriers 7, 7′, 7″ can for example be made of SiCN, SiC, or SiN.

Each insulating layer 1, 1′, 1″, 1′″ comprises an interconnection level 5, 5′, 5″, 5′″ within which lie lines 2a, 2b, 2′, 2″, 2′″, and a contact level 6, 6′, 6″, traversed by vias 3, 3′, 3′″.

The lines and vias are realized of copper or tungsten for example. It is well known to a person skilled in the art that the lines and vias may comprise a metal barrier (not represented), of TaN for example, to limit the distribution of the metallic species in the rest of the level.

The lines 2a, 2b, 2′, 2″, 2′″ and the vias 3, 3′, 3′″ are isolated from each other by insulation zones 24, 24′, 25, 25′, 25″, 26, 27, 28, 28′.

In this example, the insulation zones 25, 25′ 25″ of the interconnection levels 5, 5′, 5″, 5′″ are all of the same type, unlike those 24, 28, 24′, 28′ of the contact levels 6, 6′ of most of the insulating layers.

In this example, two dielectric materials presenting different permittivities have been used for the insulation zones 24, 28, 24′, 28′ of the contact levels 6, 6′. There can of course be more than two.

The zones 28, 28′ are realized of a first dielectric material presenting a permittivity greater than that of the material of the zones 24, 24′, called the second material. For example, the first material is a ULK dielectric material, for example dense SiOC presenting a permittivity of about 3, while the second material is an ELK dielectric material, for example porous SiOC presenting a permittivity which is less than or equal to 2.5.

One can of course do otherwise: for example, the second material can be a carbon-doped polymer such as the polymer known under the commercial name SiLK, distributed by Dow Chemical.

In this example, the zones 25, 25′, 25″ are realized of the same material as the zones 24, 24′, but they can of course be of different materials.

The zones 28, 28′ are adjacent to the corresponding lines 2a, 2b, 2′, 2a′, 2b′. In this example, the zones 28, 28′ are self-aligned with the corresponding lines 2a, 2b, 2′, 2a′, 2b′.

The total capacitance Cₗᵢₙₑ between two lines 2a′, 2b′ of a same interconnection level 5′ can be modeled as the contribution of the terms:

Cₗᵢₙₑ=Cₐᵣₑₐ+C¹_{fringe}+C²_{fringe}

where Cₐᵣₑₐ indicates the capacitance created along the field lines which pass through the insulation zone 25′,

and C¹_{fringe},C²_{fringe} indicate the fringe capacitance created along the field lines which respectively pass through the insulation zones 24′ and 24.

C_{fringe} also comprises the contribution of the field lines which pass through the barrier portion 7′ between the lines 2a′, 2b′.

The capacitances C¹_{fringe},C²_{fringe} are proportional to the permittivity of the zones traversed by the respective field lines and are therefore relatively low, such that the total line capacitance Cₗᵢₙₑ between the two lines 2a′, 2b′ is also relatively low.

In addition, the interlayer capacitance C_{layer} between two lines 2b, 2b′ of two successive insulating layers 1, 1′ can be written as:

C_{layer}=C′ₐᵣₑₐ+2*C′_{fringe}

where C′ₐᵣₑₐ indicates the capacitance created along the field lines which traverse the insulation zone 28,

and C′_{fringe} indicates the fringe capacitance created along the field lines traversing one of the insulation zones 24. Due to the nature of the zones 24, the fringe capacitance C′_{fringe} has a relatively low value.

The coexistence within a same level of insulation zones of different materials thus improves the performance of the electronic circuit.

The reference 20 indicates a part of the electronic circuit corresponding to a connection pad for connecting with the circuit exterior. As the dimensions of the pad are relatively large compared to the typical dimensions of the circuit core, there is less need for high electrical performance in the part 20 corresponding to the pad. However, this part may be required to withstand the strains of pad soldering and resin injection. It is possible to realize the insulation zones of the contact level of the part 20 of the same dielectric, presenting a relatively high Young's modulus, while using two different dielectrics for the insulation zones of the contact level in the parts of the circuit which require increased performance. Thus, the parts of the circuit can be adapted to the anticipated demands.

The upper layer 1′″ is such that the insulation zones of its levels are all realized of the same dielectric material presenting a relatively high Young's modulus, for example the first material. The upper layer is the last layer in the superimposed insulating layers.

The presence of certain parts (part 20, layer 1′″) in which the contact levels have insulation zones of a material with relatively high permittivity allows reinforcing the mechanical resistance of the entire circuit.

FIG. 3 shows an example of a portion of an electronic circuit according to one embodiment of the invention. In this example, certain insulation zones 30, 30′ of certain layers 1, 1′ comprise air or vacuum gaps. Other insulation zones 26, 27, 28 are realized of a dielectric presenting a relatively high permittivity, for example of dense SiOC.

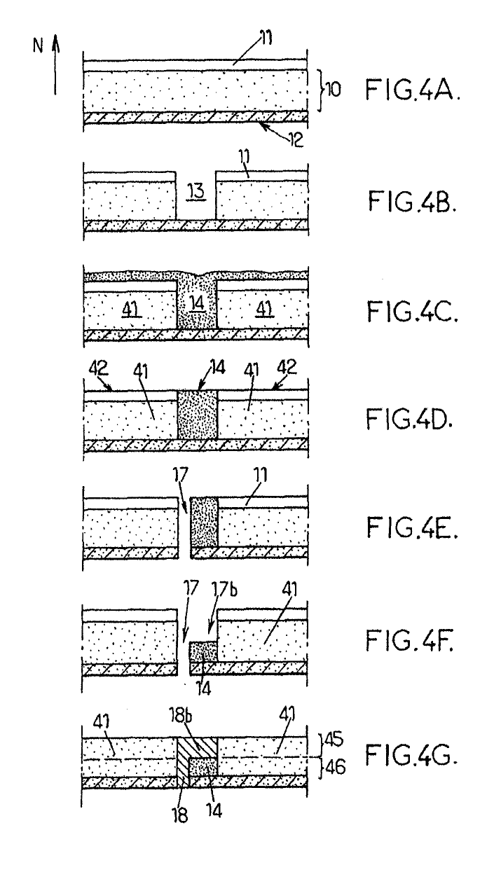

FIGS. 4A to 4G show an example of a circuit fabrication process according to one embodiment of the invention. In what follows, the basic steps of the process which are known to a person skilled in the art are not reiterated in detail.

In a substrate 12 of silicon for example, possibly comprising a dielectric barrier as well as other layers not represented, a first dielectric material, here porous SiOC, is deposited so as to form a layer 10. The deposition can occur via a PECVD (plasma enhanced chemical vapor deposition) process for example, or any other process.

A hard mask layer HM 11 is also deposited, as represented in FIG. 4A. It is advantageous if the layer 11 is of metal, for example TiN, or dielectric, for example SiN or SiCN.

As illustrated in FIG. 4B, a trench 13 is formed in the layer 10, for example by performing masking, photolithography, and dry etching operations.

In the description there is only a small number of trenches. A person skilled in the art is well aware that in actuality, the number of trenches etched simultaneously in a wafer can be relatively high, for example on the order of a million per wafer, and that only a small number of trenches is described here for easier comprehension of the process.

As illustrated in FIG. 4C, this trench 13 is filled with a second dielectric material presenting a permittivity greater than that of the first dielectric material, for example dense SiOC, thus defining insulation zones 14, 41 realized of different materials. The second dielectric material can be deposited via a PECVD process for example, or any other process.

A smoothing step substantially eliminates the second dielectric material from the zones 42 of the surface which correspond to the insulation zones 41, such that the hard mask layer 11 is level with the surface as represented in FIG. 4D. The smoothing step can be achieved using a CMP (Chemical Mechanical Polishing) process or any other known process.

Another trench 17 is formed, for example by performing masking, photolithography, and dry etching operations. In this example, the position of the trench 17 and the position of the trench 13 are partially combined, meaning that the position of the trench 17 partially covers the position of the trench 13, as illustrated in FIG. 4E.

A third trench 17b is also formed.

In this example, the trench 17 allows the realization of a via, while the trench 17b allows the realization of a line.

The trench 17 is dug beyond the dielectric barrier 12, while the trench 17b does not descend down to the dielectric barrier 12. The zone 14 is therefore reduced.

The location of the trench 17b and the location of the trench 13 are combined, as illustrated in FIG. 4F. In particular, the mask of the hard mask layer 11 can be reused as the mask for the trench 17b. This avoids the repetition of certain operations such as lithography mask operations.

Lastly, as illustrated in FIG. 4G, the trenches 17, 17b are filled in with metal, for example copper, to form a line 18b and a via 18, and a smoothing step is performed in order to level the surface. The hard mask layer 11 can be eliminated at this time.

An insulating layer with two levels 45, 46 is thus obtained, with one of the two levels comprising insulation zones 14, 41 realized of different materials. As the same hard mask 11 was used, the zone 14 and the line 18b are self-aligned.

This process, based on a dual damascene method, is only given as an indication. Note that as the hard mask layer 11 is used twice, for forming the placement for the insulation zone 14 as well as the placement for the line 18b, no additional lithography masking operations are done than in the known processes of the prior art.

Alternatively, a process based on a simple damascene method can be used. In this case, one can for example form a first trench, fill it with a metal, execute a CMP polishing step, then form a second trench adjacent to the first trench by adding a supplemental lithography step followed by dry etching, fill it with a dielectric material, and execute a CMP polishing step. The two trenches are sufficiently deep to traverse the layer in which they are etched. Thus a contact level is obtained with a via at the position of the first trench, and an insulation zone at the position of the second trench. All that remains is to create an interconnection level in order to obtain a complete layer, which can be realized by depositing a dielectric material on the contact level, forming a trench in the deposited material, then filling this trench with metal in order to form a line.

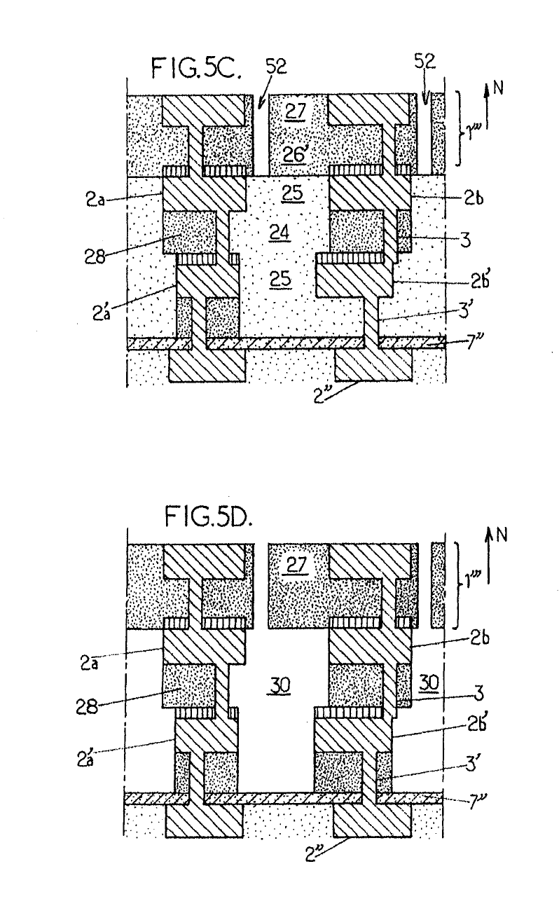

The FIGS. 5A to 5D show an example of a circuit fabrication method according to one embodiment of the invention. This method allows obtaining superimposed insulating layers in which some of the insulation zones comprise air gaps.

One begins with a first insulating layer 1′ similar to the layer obtained by the process illustrated in FIGS. 4A to 4G, and mounted on a dielectric barrier 7″. The contact level for this layer therefore comprises insulation zones 28 of a first dielectric material, and insulation zones 24 of a second dielectric material.

A self-aligned barrier labeled 51 in FIG. 5A is deposited, for example a barrier of copper silicide or CoWP, using a known process.

As illustrated in FIG. 5B, a second insulating layer 1 is formed, using for example a process similar to the one illustrated by FIGS. 4A to 4G. A self-aligned barrier 51 is also deposited.

One can continue to form insulating layers (not represented). Lastly, an upper insulating layer 1′″ is formed, with the insulation zones 26, 27 of this layer being realized of a dielectric material presenting a relatively high permittivity coefficient, for example the first dielectric material.

Openings 52 reaching the dielectric material of the zones 24, 25 are realized in the upper layer 1′″, as illustrated in FIG. 5C, for example by performing masking, photolithography, and wet etching operations.

Lastly, the second dielectric material is removed, for example by placing it in contact with an agent which removes the second dielectric material. The wafer supporting these superimposed layers 1, 1′, 1′″ is immersed in said agent to remove the second dielectric material. For example, the first dielectric material is of dense SiOC and the second dielectric material is of SiO₂. Said removal agent is for example hydrofluoric acid (HF), able to dissolve SiO2 but resisted by dense SiOC. The removal agent can dissolve the material in zones 24, 25 by passing through the openings 52, forming air gaps, as illustrated in FIG. 5D.

In another example, the second dielectric material is removed by raising the temperature. For example, the first dielectric material is dense SiOC and the second dielectric material is a thermally degradable polymer such as the SiLK polymer, for example. The temperature is increased at least to a temperature at which SiLK degrades. The openings 52 allow the evacuation of the degraded polymer material.

Of course, circuits with air gaps can be formed using different processes. For example, the material used for the insulation zones 26, 27 of the upper layer 1′ can be of a porous material resistant to the removal agent. There is then no need to form the openings 52 in the FIGS. 5C and 5D.

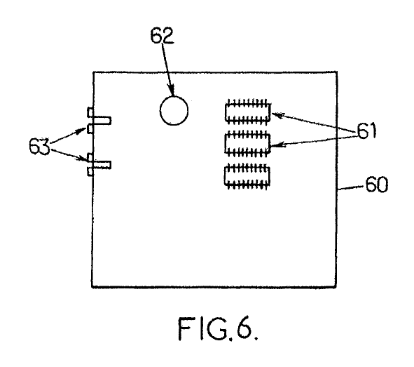

FIG. 6 shows an example of an electronic board according to one embodiment of the invention. The board 60 comprises pads 63, a coil 62, connections not represented, and electronic chips 61 integrating a circuit according to one embodiment.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet, are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for fabricating an integrated electronic circuit, comprising:
forming superimposed insulating layers and metal elements distributed within said insulating layers, the forming comprising, for at least one insulating layer of said superimposed insulating layers:
forming a first dielectric layer by depositing a first dielectric material on a substrate;
forming a first trench in the first dielectric layer;
filling in the first trench with a second dielectric material which is different from the first dielectric material, such that the first dielectric layer now comprises insulation zones of the first dielectric material and insulation zones of the second dielectric material;
executing a smoothing step so as to eliminate substantially the second dielectric material from zones of a surface of the first dielectric layer which correspond to the insulation zones of the first dielectric material;
forming a second trench in the first dielectric layer; and
forming a first metal element by filling said second trench with metal, wherein the second dielectric material has a higher permittivity than the first dielectric material.

2. The method of claim 1, further comprising:
forming a third trench; and
forming a second metal element by filling said third trench with metal.

3. The method of claim 2, wherein at least two of the trenches have positions that are adjacent or at least partially combined.

4. The method of claim 2, wherein:
two of the trenches having positions that are combined; and
the same mask is used for forming said two of the trenches.

5. The method of claim 1, further comprising:
removing at least part of the first dielectric material.

6. A method, comprising:
forming an integrated circuit, wherein forming the integrated circuit includes:
forming a first insulating layer on a substrate, forming the first insulating layer including forming first and second insulation zones of first and second dielectric materials, respectively, the first dielectric material having a permittivity coefficient that is different than a permittivity coefficient of the second dielectric material;
forming a first conductive via in the first insulating layer, the first conductive via being immediately adjacent to the second insulation zone, and the first insulation zone being between the first conductive via and the first insulation zone;
forming a first conductive line in the first insulation zone, the first conductive line contacting the first conductive via; and
forming a second insulating layer on the first insulating layer after completing the forming of the first insulating layer, the first and second insulation zones, the first conductive via, and the second conductive line.

7. The method of claim 6, wherein forming the integrated circuit includes:
forming a trench in the first insulation zone by etching through the first insulation zone, wherein:
forming the second insulation zone includes forming the second insulation zone in a first lower side portion of the trench;
forming the first conductive via includes forming the first conductive via in a second lower side portion of the trench; and
forming the first conductive line includes forming the first conductive line in an upper portion of the trench.

8. The method of claim 7, wherein forming the first insulation zone includes:
completely filling the trench with the second dielectric material; and
etching the second dielectric material from the second lower side portion of the trench and from the upper portion of the trench.

9. The method of claim 8, wherein:
forming the trench includes etching the trench in the first insulation zone using a mask; and
etching the second dielectric material from the upper portion of the trench uses the same mask used in forming the trench.

10. The method of claim 6, wherein forming the integrated circuit includes:
forming a third insulation zone in the first insulating layer, the third insulation zone being of the second dielectric material, the conductive via being positioned between the first and third insulation zones.

11. The method of claim 6, wherein the conductive via is formed before forming the conductive line.

12. The method of claim 6, wherein forming the integrated circuit includes:
forming a second conductive via and a second conductive line in the second insulating layer after completing the forming of the first insulating layer, the first and second insulation zones, the first conductive via, and the second conductive line.

13. The method of claim 6, wherein the permittivity coefficient of the second dielectric material is greater than the permittivity coefficient of the first dielectric material

14. The method in claim 6, wherein the second dielectric material has a Young's modulus greater than a Young's modulus of the first dielectric material.

15. The method of claim 6, further comprising:
forming a packaged electronic chip by forming a package on the integrated circuit.

16. The method of claim 15, further comprising:
forming a device, wherein forming the device includes mounting the packaged electronic chip on a circuit board.
